(19) United States
(12) Patent Application Publication
(10) Pub. No.: US 2018/0180573 A1
(43) Pub. Date: Jun. 28, 2018

(54) GAS DETECTION SYSTEMS AND METHODS USING GRAPHENE FIELD EFFECT TRANSISTORS

(71) Applicant: The Regents of the University of California, Oakland, CA (US)

(72) Inventors: Liwei Lin, Oakland, CA (US); YuMeng Liu, Oakland, CA (US)

(73) Assignee: The Regents of the University of California, Oakland, CA (US)

(21) Appl. No.: 15/736,642

(22) PCT Filed: Jun. 20, 2016
(86) PCT No.: PCT/US2016/038415

§ 371 Date: Dec. 14, 2017

Related U.S. Application Data
(60) Provisional application No. 62/181,680, filed on Jun. 18, 2015.

(51) Int. Cl. G01N 27/414; H01L 29/16; H01L 29/786

(52) U.S. Cl. CPC G01N 27/4141; H01L 29/78684; H01L 29/1606; G01N 27/4146

(57) ABSTRACT

A gas detection system for selectively detecting one or more gases from a mixture of gases includes a gas sensor that includes at least one graphene field effect transistor (GFET). The GFET includes a source electrode, a drain electrode, a graphene channel layer, a gate electrode arranged proximate the graphene channel layer, and a dielectric layer between the graphene channel layer and the gate electrode. The gas detection system also includes a modulation system electrically connected to the gate electrode to modulate a response of the GFET to the gas sample, a detector electrically connected to the source electrode and the drain electrode to detect a modulated signal containing information concerning a response of the GFET to the gas sample during modulation by the modulation system, and a signal processor configured to communicate with the detector to receive the modulated signal. The signal processor is further configured to selectively determine a concentration of at least one gas in the gas sample based at least on the modulated signal.

This application claims priority to U.S. Provisional Application No. 62/181,680 filed Jun. 18, 2015, the entire content of which is hereby incorporated by reference.

### BACKGROUND

### 1. Technical Field

Some embodiments of the present invention relate to gas detection systems and methods, and more particularly to gas detection systems and methods for selectively detecting one or more gases from a mixture of gases.

### 2. Discussion of Related Art

An electronic nose (E-nose) or artificial olfactory system is a sensor or sensor array that collects information from the gaseous environment and provides real time monitoring of the composition of the gas mixture or odors. For industrial plants, i.e. oil refinery factories, automobiles and households, E-nose can be installed in the desired areas for monitoring multiple critical/toxic gas concentration. For personal well-being, E-nose can be integrated into cell phones or wearable electronic devices collecting biomedical information for disease diagnoses, or monitoring the quality of surrounding air.

The omniscient installation of E-noses demands merits such as low cost, low power consumption, high sensitivity and decent selectivity for discriminating different gases of interest. Chemiresistor and ChemFET are among the lowest cost-effective solutions for chemical gas detection and are widely used for various gas-monitoring purpose. The working principle of such sensors is based on the charge transfer that takes place at the gas-solid interface that changes the electrical conductance of the sensing body proportionally to the gas concentration.

Previously, the selectivity towards a particular type of gas, if multiple charge-transfer favorable gases are presented, was mostly achieved by decorating a thin layer of functionalized polymer or noble metal particles on the sensor surface. However, both the cost of fabrication and the design of the specific decorations can dramatically increase given the scenario of monitoring complex gaseous mixtures. Moreover, there still remains great concern for the genuine selectivity due to the potential crosstalk from different adsorbed molecules on the same sensing unit. Other previous efforts like machine learning and neuron network algorithms can enhance the selectivity but usually require massive sensing identifiers as well as extensive power of computation.

Recently, graphene has demonstrated its superior performance and great application potential in gas sensing, i.e. ultra-low power consumption, individual molecule detection and wide sensitive range of gas type. However the selectivity of graphene based gas sensor especially in multiple gas mixture has not been well explored. There thus remains a need for improved gas detection systems and methods for selectively detecting one or more gases from a mixture of gases

### SUMMARY

A gas detection system for selectively detecting one or more gases from a mixture of gases according to some embodiments of the current invention includes a gas sensor that includes at least one graphene field effect transistor (GFET). The GFET includes a source electrode, a drain electrode spaced apart from the source electrode, a graphene channel layer extending between and in electrical connection with the source and drain electrodes, the graphene channel layer having at least a portion of a surface thereof exposed to be able to make contact with a gas sample, a gate electrode arranged proximate the graphene channel layer, and a dielectric layer between the graphene channel layer and the gate electrode. The gas detection system also includes a modulation system electrically connected to the gate electrode to modulate a response of the GFET to the gas sample, a detector electrically connected to the source electrode and the drain electrode to detect a modulated signal containing information concerning a response of the GFET to the gas sample during modulation by the modulation system, and a signal processor configured to communicate with the detector to receive the modulated signal. The signal processor is further configured to selectively determine a concentration of at least one gas in the gas sample based at least on the modulated signal.

A gas-detection method according to some embodiments of the current invention includes exposing a GFET to a gas sample. The GFET includes a source electrode, a drain electrode spaced apart from the source electrode, a graphene channel layer extending between and in electrical connection with the source and drain electrodes, the graphene channel layer having at least a portion of a surface thereof exposed to be able to make contact with the gas sample, a gate electrode arranged proximate the graphene channel layer, and a dielectric layer between the graphene channel layer and the gate electrode. The method also includes modulating a response of the GFET to the gas sample by controlling a voltage applied to the gate electrode, detecting a response of the GFET during the modulating to provide a modulated signal, and processing the modulated signal to selectively determine a concentration of at least one gas in the gas sample.

### BRIEF DESCRIPTION OF THE DRAWINGS

Further objectives and advantages will become apparent from a consideration of the description, drawings, and examples.

FIG. 1 is a plot of Footprint versus Power Cost per Sensor for some convention gas detectors compared to gas detectors according to some embodiments of the current invention (see dashed circle, lower left in plot).

FIG. 2 is a schematic illustration of a gas detection system for selectively detecting one or more gases from a mixture of gases according to some embodiments of the current invention.

FIG. 3 is a schematic illustration of a graphene field effect transistor (GFET) according to some embodiments of the current invention.

FIGS. 4A and 4B are circuit diagrams to help explain some concepts of a gas detection system for selectively detecting one or more gases from a mixture of gases according to some embodiments of the current invention.

FIG. 5 is a schematic illustration of a gas detection system for selectively detecting one or more gases from a mixture of gases according to some embodiments of the current invention.

FIGS. 6A and 6B are schematic illustrations for a gas sensor array according to some embodiments of the current invention.

FIGS. 7A-7D shows examples according to an embodiment of the current invention of the graphene gas sensor responses under different gate voltages, showing channel resistance a) drops to a lower value; b) rises then drops to a lower value (passing the Dirac Point on the dashed line working gate voltage); c) rises then drops to a higher value; and d) rises to a higher value, under different gate bias voltages.

FIG. 8A-8C show the electron donation process from adsorbed molecule to graphene channel.

FIG. 9A-9B show a) The gas molecule becomes charged impurity (carrier scattering center) after transferring electrons to the graphene channel. The electrical scattering potential is long-range, or the “Coulomb scattering potential”—when the screening effect is weak due to low carrier concentration in graphene; b) The electrical scattering potential can be reduced into short-range, or the “delta scattering potential”—when the screening effect is strong due to high carrier concentration in the channel. The carrier concentration is tunable by the gate voltage. In the illustration, “d” is the equilibrium distance between gas molecule and the graphene surface, and “r” is distance between charged molecules and scattered carriers.

FIG. 10A-10B show a) The graphene FETs are wire-bonded and electrically connected to the bread board. The p-doped silicon wafer is used as the gate electrode. b) The scale bar is 10 um. The graphene channel has the darker blue color. The “transfer length method” and “Hall bar” are designed to measure the contact resistance and mobility of the graphene device, respectively. A total of 5 transistors are shown.

FIG. 11 shows the gas sensing setup used in Example 3. The gas vapor flow rate can be controlled at a level of 100 ppm/s using the microliter pump. The volume of the chamber is around 20 mL.

FIG. 12A-12D show the real time conductance versus gate voltage of graphene FET (width 10 um and length 70 um) under constant gas flow rate at 750 ppm/s for (a) p-type dopant NO₂, (b) n-type dopant NH₃, (c) n-type dopant H₂O, and (d) n-type dopant CH₃OH vapors. The time interval between each measurement is 15 s. The Dirac Point can be observed at the minimum conductance point. The mobility can be calculated using Eq. (3.3).

FIG. 13A-13D show the real time linear dependence between the reciprocal of the long-range scattering limited carrier mobility and the Dirac Point voltage for four types of gases. V_{g,c}=V_{g,Dirac}±2V is used for calculating the mobility in the electron/hole regimes, respectively, a) The real time linear dependence of as-calculated values in the electron regime of the graphene FET, and b) summed data points in the electron region of the graphene FET; c) the linear dependence of as-calculated values in the hole regime of the graphene FET, and d) summed data points in the hole regime of the graphene FET.

### DETAILED DESCRIPTION

Some embodiments of the current invention are discussed in detail below. In describing embodiments, specific terminology is employed for the sake of clarity. However, the invention is not intended to be limited to the specific terminology so selected. A person skilled in the relevant art will recognize that other equivalent components can be employed and other methods developed without departing from the broad concepts of the current invention. All references cited anywhere in this specification, including the Background and Detailed Description sections, are incorporated by reference as if each had been individually incorporated.

Accordingly, some embodiments of the current invention provide devices and methods for monitoring a wide range of gases at the same time using graphene field effect transistor (GFET) sensor arrays without specific surface decoration. Each sensing unit in an embodiment of the current invention can respond to every gas component in the mixture, yet the cross-reactive response can be discriminated from sensor to sensor by a different DC gate voltage. Thanks to the nonlinear relationship between the adsorbed molecule-induced field effect mobility change and the gate voltage bias on the GFETs, a group of linear equations can be derived and solved to decouple the individual contribution of each gas component in the mixture. For a sensor array with m×m in size, at most m² known gases can be presented and discriminated directly in the mixture substantially concurrently. Further details of this and other embodiments of the current invention are described in more detail below.

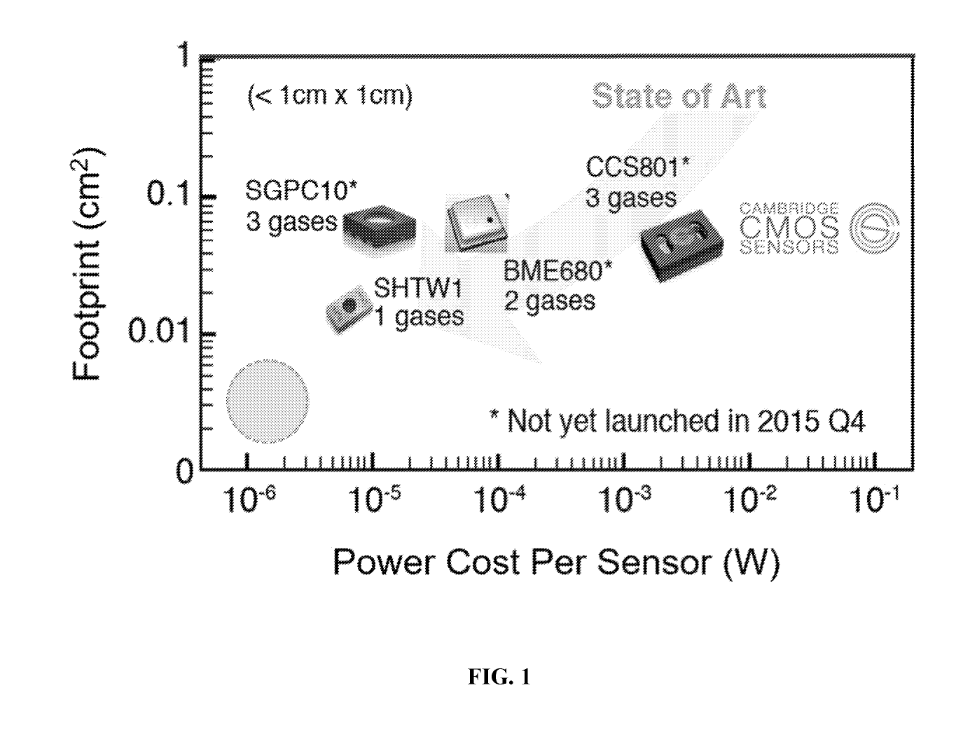

FIG. 1 is a schematic illustration showing the sensor footprint versus power cost for conventional gas sensors currently or soon to be available, compared to that of sensors according to some embodiments of the current invention illustrated as a dashed circle in the lower left hand corner of the drawing. Note that FIG. 1 is a log-log plot, thus indicating a very substantial decrease in footprint and power cost can be achieved according to some embodiments of the current invention.

Before describing some particular embodiments in more detail, the following describes some embodiments more generally. Some embodiments of the current invention provide a method for concurrently detecting target gases in a gaseous mixture. The method according to some embodiments includes using cross-reactive graphene FETs in a sensor array without specific surface coating, DC offsetting a gate voltage of the graphene FETs in the sensor array, and decoupling contributions from non-target gases in said gaseous mixture to detect said presence of said target gases.

Some embodiments of the current invention provide a device to selectively sense target gases in a gaseous mixture, the device using a graphene FET. The graphene FET measures real time conductance as a function of a gate voltage of the graphene FET. The device decouples contributions from non-target gases in the gaseous mixture to detect the target gases.

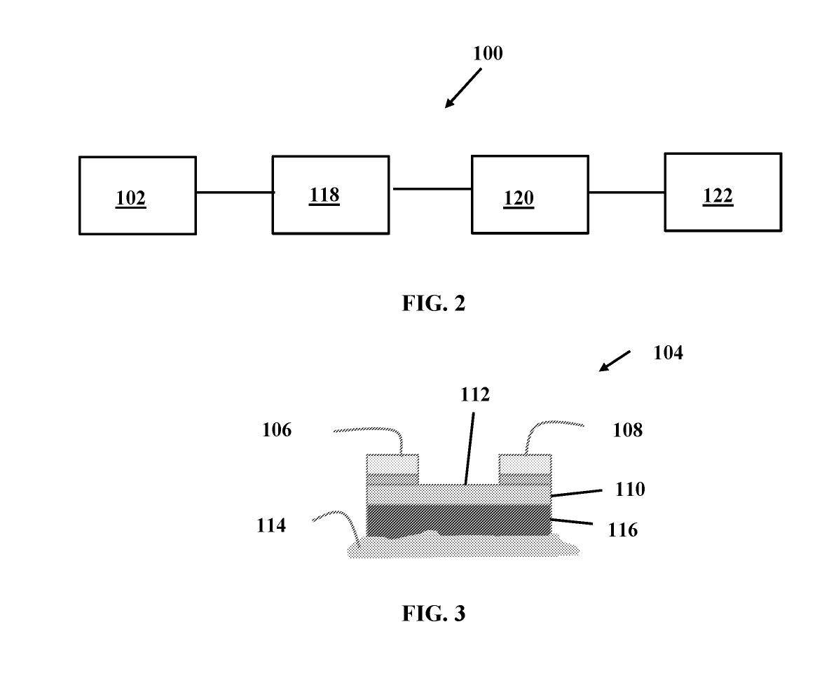

FIG. 2 is a schematic illustration of a gas detection system 100 for selectively detecting one or more gases from a mixture of gases according to an embodiment of the current invention. The gas detection system 100 includes a gas sensor 102. The gas sensor 102 includes at least one graphene field effect transistor (GFET) 104, as is shown in more detail in FIG. 3. The GFET 104 includes a source electrode 106, a drain electrode 108 spaced apart from the source electrode 106, and a graphene channel layer 110 extending between and in electrical connection with the source and drain electrodes (106, 108). The graphene channel layer 110 has at least a portion of a surface 112 thereof exposed to be able to make contact with a gas sample. The GFET 104 also includes a gate electrode 114 arranged proximate the graphene channel layer 110, and a dielectric layer 116 between the graphene channel layer 110 and the gate electrode 114.

The gas detection system 100 also includes a modulation system 118 electrically connected to the gate electrode 114 to modulate a response of the GFET 104 to the gas sample; a detector 120 electrically connected to the source electrode 106 and the drain electrode 108 to detect a modulated signal containing information concerning a response of the GFET 104 to the gas sample during modulation by the modulation system 118; and a signal processor 122 configured to communicate with the detector 120 to receive the modulated signal. The signal processor 122 is further configured to selectively determine a concentration of at least one gas in said gas sample based at least on the modulated signal.

The term “response” of the graphene field effect transistor (GFET) according to some embodiments of the current invention is intended to include an output signal being changed due to the presence of a gas sample as compared to the absence of the gas sample. The response can be dynamic or stationary in a time period. For example, a gas sample that changes over the time period can result in a response that also changes with time. The gas sample can be, but is not limited to, a mixture of a plurality of gas types, such as, but not limited to, two, three, four, five, six and even more types of gases. The term “response” can include, but is not limited to, at least one of field effect mobility, effective mobility, Hall Effect mobility, carrier concentration, Dirac Point voltage, conductivity, noise spectral density, contact resistance, or work function.

The response of the GFET can also depend on external and/or applied effects, such as an applied gate voltage. According to some embodiments of the current invention, the “response” can be modulated by selecting a gate voltage and/or selecting a plurality or time varying gate voltages.

1. “Response”:

a. the response can be either a single point value, or a vector that contains a response readout over a certain period of time.

b. Such response can be a readout at either a stationary (or quasi-stationary) state, or a transient state.

c. Such transient state can be caused by, but not only limited to, changing the modulation pattern of gate voltage, or changing the presence (concentration) of a gas in the sample.

2. “Graphene”:

a. The graphene layer is a gas sensitive layer that contains either monolayer graphene, double layer graphene, graphene flakes or their combination.

b. Such graphene can be either in a pristine, doped, or defect state.

c. Such defect and doped state can be achieved by either removing the carbon atoms in graphene, adding external dopant onto graphene, or substituting carbon atoms in graphene by external dopant. The external dopants can be, but are not only limited to, atoms or functional groups that contain boron, nitrogen, phosphor, oxygen, hydrogen, or aluminum.

3. “Gate Voltage Modulation”

a. The gate voltage is the voltage difference between the gate electrode and source electrode or drain electrode of the GFET, whichever is larger.

b. Such voltage modulation, either stationary or alternating, changes the electronic and chemical properties of graphene layer.

c. Such properties can be, but are not limited to, the work function, Fermi level, Dirac Point voltage, field effect carrier mobility, Hall Effect carrier mobility, and electron affinity of graphene layer.

The term “a gas” is intended to refer to a gas of substantially pure chemical composition. However, the phrase “a gas sample” is intended to include both cases of a gas of substantially pure chemical composition as well as cases of gas mixtures.

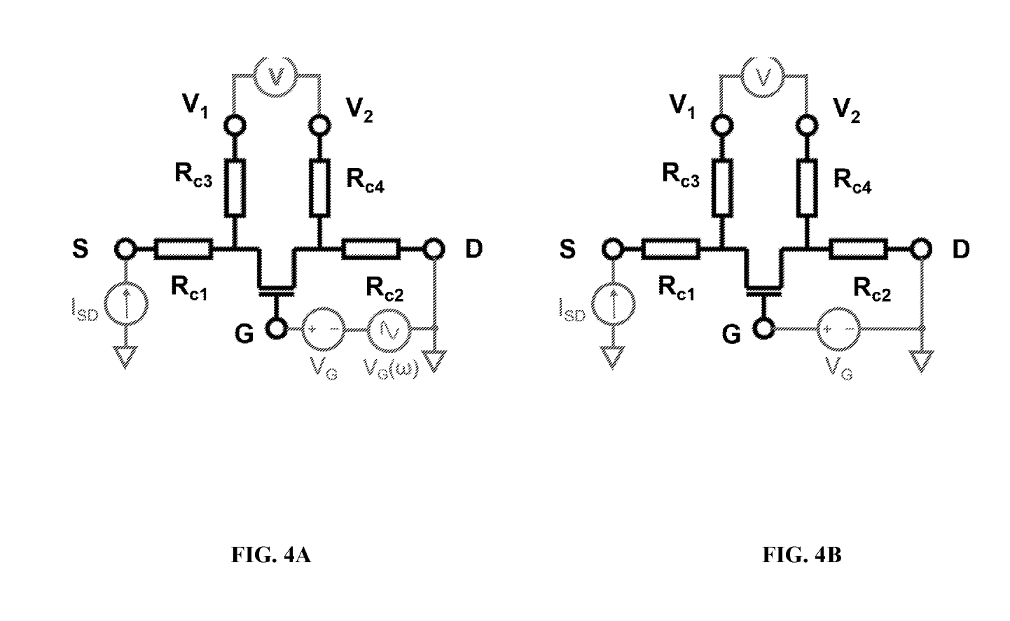

FIGS. 4A and 4B are circuit diagrams that illustrate examples of the gas detection system 100 in which the gas sensor 102 has a single GFET with source (S), drain (D) and gate (G) electrodes. The gas sensor 102 is not limited to a single GFET in other embodiments of the current invention. The examples in FIGS. 4A and 4B help illustrate one possible structure according to an embodiment of the invention, without limitation. In addition, FIGS. 4A and 4B do not show any example of the signal processor 122. In the example of FIG. 4A, the time varying voltage source applied between G and D, and any associated electronics, is an example of the modulation system 118. In the example of FIG. 4B, the DC voltage source applied between G and D, and any associated electronics, is another example of the modulation system 118. However, the modulation system 118 is not limited to only these examples. In the examples of FIGS. 4A and 4B, the detector 120 determines voltage V between S and D as modulated by the voltage applied to G. The voltage V can be used to determine the current I_{SD} flowing through the graphene channel layer of the GFET, for example. The response of the GFET to the applied gate voltage V_{G} and/or V_{G}(ω) results in a change in I_{SD} compared to when no modulation is applied, such as V_{G}=0, for example. One should note, however, that the detector 120 is not limited only to this example.

The signal processor 122 is configured to communicate with the detector 120 so as to receive the modulated signal. The signal processor 122 could be hard wired to the detector, such as electrically or optically, and/or could be wirelessly connected, as long as the modulated signals are received in some manner to be processed. The signal processor 122 could be a programmable device and/or a device hard wired to perform the specified computations and/or logic functions. For example, the signal processor could be an ASIC or an FPGA in some embodiments. In another example, the signal processor can be, but is not limited to a microprocessor. In some embodiments, a central processing unit (CPU) can be the signal processor. In some embodiments, any type computer and/or networked computers can be the signal processor 122, which could include, but is not limited to, one or more of any of a smart phone, a tablet computer, a laptop computer, a mainframe computer, or any combination thereof. Although the signal processor is configured to perform functions, such as computations and/or logic operations, it is a device defined by its structure.

In some embodiments, the signal processor 122 is further configured to selectively determine a concentration of each of a plurality of gases in the gas sample based at least on the modulated detection signal.

In some embodiments, the modulation system 118 applies a plurality of gate voltages to the GFET 104 at a corresponding plurality of different times such that the detector 120 provides a plurality of modulated detection signals to the signal processor 122. The signal processor 122 in this embodiment is further configured to selectively determine a concentration of each of a plurality of gases in the gas sample based at least on the plurality of modulated detection signals.

In some embodiments, the plurality of detection signals provide information concerning a plurality of response-influencing parameters, and the signal processor 122 is further configured to selectively determine the concentration of each of the plurality of gases in the gas sample based at least partially on the information concerning the plurality of response-influencing parameters. In some embodiments, the plurality of response-influencing parameters can include, but are not limited to, at least one of field effect mobility, effective mobility, Hall Effect mobility, carrier concentration, Dirac Point voltage, conductivity, noise spectral density, contact resistance, or work function.

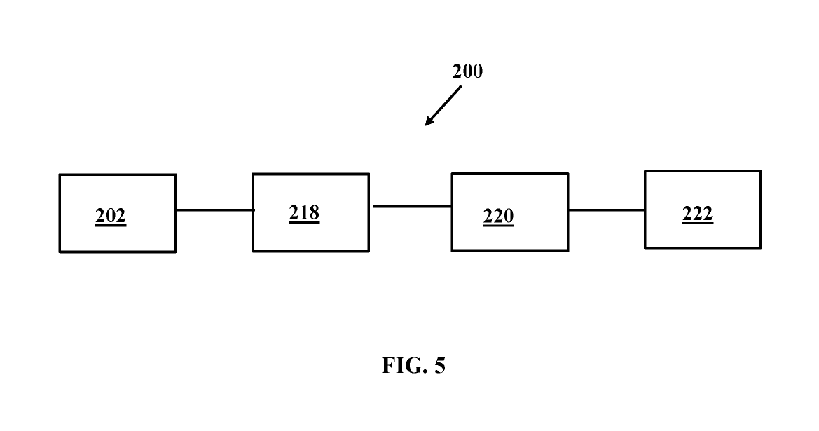

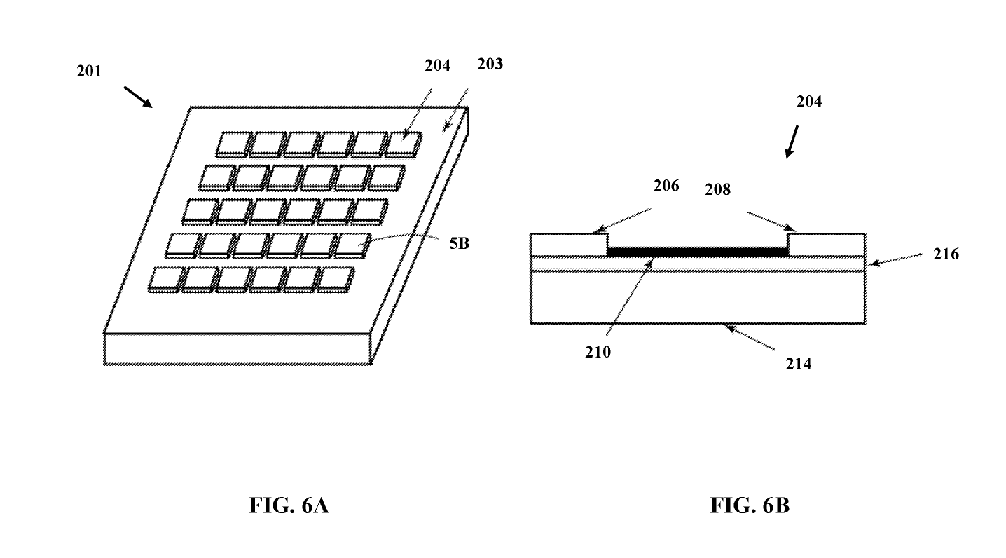

FIG. 5 is a schematic illustration of a gas detection system 200 for selectively detecting one or more gases from a mixture of gases according to another embodiment of the current invention. The gas detection system 200 includes a gas sensor 202. The gas sensor 202 includes an array 201 of individual GFETs 204, which can be formed on or attached to a substrate 203, such as, but not limited to a printed circuit board (FIG. 6A). FIG. 6B shows a cross sectional view of one of the GFETs 204 from the array. In some embodiments, the plurality of GFETs can all be substantially the same in structure as GFET 204. However, the general concepts of the current invention are not limited to all of the plurality of GFETs being substantially the same in structure. In addition, the general concepts of the current invention are not limited to any particular array pattern or any particular number of GFETs in the array.

In FIG. 6B, the GFET 204 includes a source electrode 206, a drain electrode 208 spaced apart from the source electrode 206, and a graphene channel layer 210 extending between and in electrical connection with the source and drain electrodes (206, 208). The graphene channel layer 210 has at least a portion of a surface thereof exposed to be able to make contact with a gas sample. The GFET 204 also includes a gate electrode 214 arranged proximate the graphene channel layer 210, and a dielectric layer 216 between the graphene channel layer 210 and the gate electrode 214.

The gas detection system 200 also includes a modulation system 218 electrically connected to the gate electrode 214 of each of the plurality of GFETs to modulate a response of each GFET 204 of the array 201 to the gas sample; a detector 220 electrically connected to the source electrode 206 and the drain electrode 208 to detect a modulated signal containing information concerning a response of each GFET 204 of the array 201 to the gas sample during modulation by the modulation system 218; and a signal processor 222 configured to communicate with the detector 220 to receive the modulated signal. The signal processor 222 is further configured to selectively determine a concentration of at least one gas in the gas sample based at least on the plurality of modulated signals.

In an embodiment, the signal processor 222 is further configured to selectively determine a concentration of each of a plurality of gases in the gas sample based at least on the plurality of modulated detection signals.

In an embodiment, the signal processors 122 and/or 222 can be further configured to determine the concentration of each of the plurality of gases in the gas sample using previous knowledge of responses of the GFETs to known gases.

In an embodiment, the signal processors 122 and/or 222 can be further configured to determine the concentration of the plurality of gases in the gas sample based on previous knowledge of responses of the GFET to known gases that include the plurality of gases by at least one of solving a set of linear equations, using machine learning, using principle component analysis, using a numerical fitting routine, or using an analytical fitting routine.

A gas-detection method according to an embodiment of the current invention includes exposing a GFET to a gas sample, modulating a response of the GFET to the gas sample by controlling a voltage applied to the gate electrode of the GFET, detecting a response of the GFET during the modulating to provide a modulated signal, and processing the modulated signal to selectively determine a concentration of at least one gas in the gas sample.

As noted above, gas detection systems according to some embodiments of the current invention can be very small, even with sensor array, can be run on very low power requirements, and can detect multiple gases present in a mixture of gases. Such gas sensors can have many applications, which can include, but are not limited to, measuring air quality, body hydration, basal metabolic rate, biomedical conditions, breathalyzers, detection of industrial gases, natural gas, ozone, carbon monoxide, and/or carbon dioxide, for example.

The following are some examples according to some embodiments of the current invention. The general concepts of the invention are not limited to these particular examples.

### Example 1

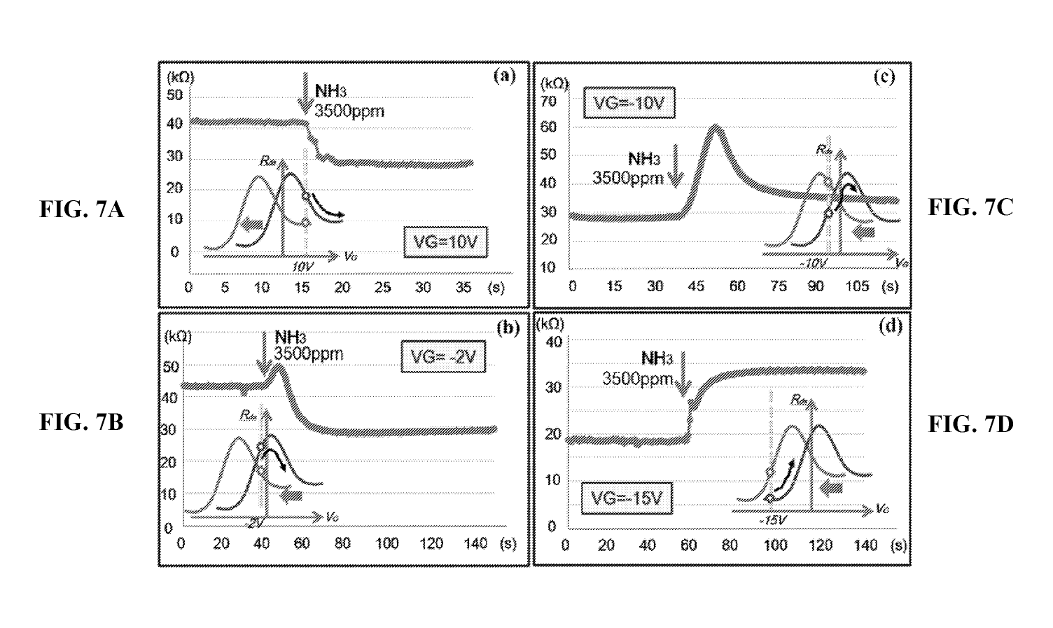

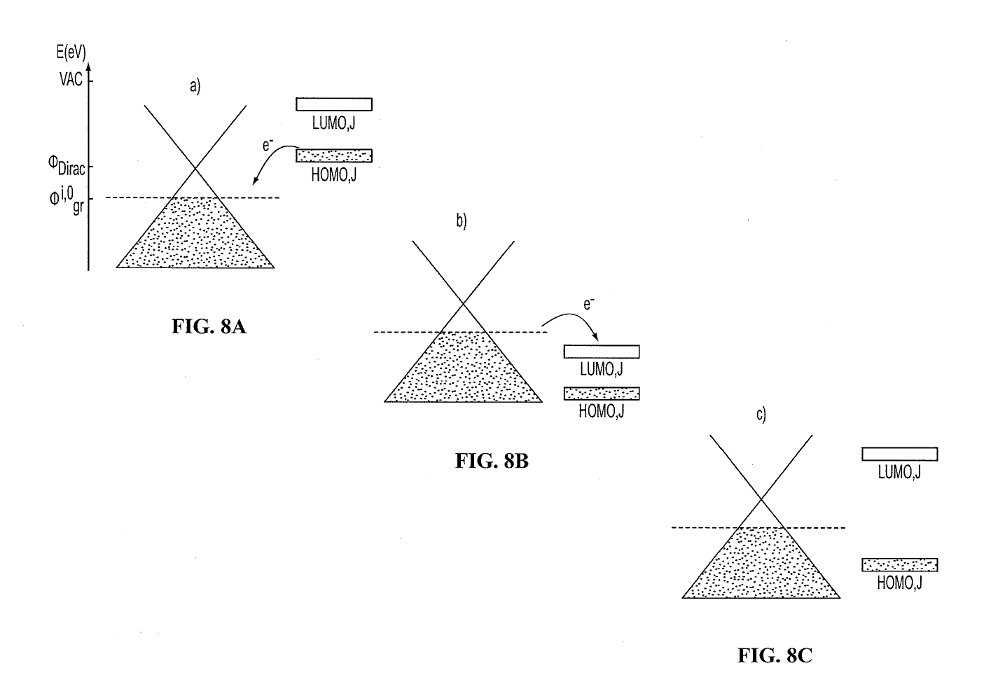

In one example, according to an embodiment of the current invention, we examined the gas sensor response under different gate voltages. FIGS. 7A-7D illustrate the response of a flexible GFET gas sensor when exposed to 3500 ppm of ammonia under different gate voltages. (See Liu, Y., et al, A FLEXIBLE GRAPHENE FET GAS SENSOR USING POLYMER AS GATE DIELECTRICS, 2014 IEEE 27th International Conference on Micro Electro Mechanical Systems (MEMS), 26-30 Jan. 2014, pp. 230-233, the entire contents of which are incorporated herein by reference.)

As shown in each figure, the intersection points between the R_{DS}-V_{G} curves and the vertical dashed line (working gate voltage) determine the channel resistance. As the R_{DS}-V_{G} curve shifts from the left to right curve during the ammonia doping process, changes in the channel resistance (R_{DS}) are recorded and they behave differently under different gate voltages. For example, in FIG. 7A, the graphene channel is biased with V_{G}=10V and the transition of channel resistance starts from the intersection of the right curve and dashed line (point on right curve); follows the black vector on the right curve; and settles to a lower channel resistance at the point on the left curve. In FIGS. 7B and 7C, the black vector increases initially to pass the Dirac Point, then settles at a higher and lower magnitude as compared to the initial resistance, respectively. It is noted that passing the Dirac Point results in a resistance peak in the corresponding R_{DS}-time measurement plots, and provides direct observation of n-type doping of graphene passing through the Dirac Point shift in real time. FIG. 7D shows that under a negative gate voltage V_{G}=−15V, the channel resistance increases with time during the measurements in the R_{DS}-time curve.

### Example 2

As shown in FIG. 6A, an array 201 of m×m identical graphene FETs 204 are assembled on the substrate with the cross-sectional structure of each graphene FET 204 shown in FIG. 6B. The graphene FET 204 structure includes a monolayer of graphene 210 as the channel, three conductive contacts: source electrode 206, drain electrode 208, and a bottom gate electrode 214; the gate oxide 216 is sandwiched in between the bottom gate electrode 214 and the graphene channel 210. The top surface of graphene is open to the adsorption of mixed gas molecules. The channel current of the i^{th} graphene FET, I_{ds}ⁱ=I_{DS}ⁱ+i_{ds}ⁱ (ωt), (i=1 . . . m²), in the sensor array can be modeled as

$${I}_{ds}^{i} = \{ \begin{matrix}[ {μ}_{e}^{i} {C}_{g} ( {V}_{g}^{i} - {V}_{Dirac}^{i} ) + {σ}_{res}^{i} ] {V}_{DS} \frac{W}{L} & {V}_{g}^{i} \geq {V}_{Dirac}^{i} \\ [ - {μ}_{h}^{i} {C}_{g} ( {V}_{g}^{i} - {V}_{Dirac}^{i} ) + {σ}_{res}^{i} ] {V}_{DS} \frac{W}{L} & {V}_{g}^{i} < {V}_{Dirac}^{i}\end{matrix} \qquad ( 2.1 )$$

where V_{g}ⁱ=V_{G}ⁱ+v_{g}(ωt) is the gate voltage bias with both DC offset V_{G}ⁱ and small AC voltage v_{g}(ωt); μₑⁱ, μₕⁱ is the field effect mobility for electrons/holes respectively; C_{g} is the gate oxide capacitance per unit area; σᵣₑₛⁱ is the residual conductivity at the Dirac Point due to the electron-hole puddles induced by the fabrication-related impurities on the graphene; V_{DS} is the drain to source voltage consistently biased at 0.1V; W,L is the width and length of the graphene channel.

Without the adsorption of gas molecules of detection interest, the sensor array, in its idle state, is immersed in a background environment that is assumed not changing during the sensing duration. In its idle state, all the characteristic properties of graphene FET relax at the baselines denoted with “0”. For example, the pristine charge density of graphene FET Q_{gr}^{i,0} is

Q_{gr,0}ⁱ=−C_{g}(V_{g}ⁱ−V_{Dirac,0}ⁱ) (2.2)

and it can be either positive (V_{g}ⁱ<V_{Dirac,0}ⁱ) or negative (V_{g}ⁱ>V_{Dirac,0}ⁱ) depending on the gate voltage. Then the m² types of mixed gas molecules of detection interest are released to the sensor array, and will start to take the available adsorption sites on the homogeneous surface of graphene. The maximum density of sites available for adsorption on graphene surface is N_{gr}, which is limited by the collision radius of gas molecules. For gas molecule J on graphene FET i, a thermodynamic equilibrium of adsorption can be gradually reached when the adsorption rate equals to the desorption rate according to the Langmuir adsorption model,

$${θ}_{J}^{i} = \frac{{K}_{J}^{i} {P}_{J}}{1 + {K}_{J}^{i} {P}_{J}} \qquad ( 2.3 )$$

where θ_{J}ⁱ is the coverage rate of the total sites N_{gr}; P_{J} is the partial pressure; K_{J}ⁱ is the gas adsorption equilibrium constant on graphene surface at room temperature. Under low gas concentration and weak interaction limit

$${I}_{ds}^{i} = \{ \begin{matrix}[ {μ}_{e}^{i} {C}_{g} ( {V}_{g}^{i} - {V}_{Dirac}^{i} ) + {σ}_{res}^{i} ] {V}_{DS} \frac{W}{L} & {V}_{g}^{i} \geq {V}_{Dirac}^{i} \\ [ - {μ}_{h}^{i} {C}_{g} ( {V}_{g}^{i} - {V}_{Dirac}^{i} ) + {σ}_{res}^{i} ] {V}_{DS} \frac{W}{L} & {V}_{g}^{i} < {V}_{Dirac}^{i}\end{matrix} \qquad ( 2.1 )$$

therefore θ_{J}ⁱ=K_{J}ⁱP_{J}.

As indicated in the FIG. 7A-7C, three types of charge transfer, namely electron doping, hole doping, and no doping, can happen between the adsorbed gas molecules and the graphene surface, and the direction of charge transfer depends on the molecular orbital properties. Several critical parameters: the work function at pristine graphene Fermi level ϕ_{gr,0}ⁱ, the highest occupied molecular orbital (HOMO) ϕ_{HOMO,J}, and the lowest unoccupied molecular orbital (LUMO) ϕ_{LUMO,J} are labeled in the figure. Both ϕ_{HOMO,J} and ϕ_{LUMO,J} are molecular properties, and ϕ_{gr,0}ⁱ is the pristine work function of graphene FET subjected to gate voltage bias,

$${φ}_{gr , 0}^{i} = \{ \begin{matrix}{φ}_{Dirac} - \frac{ℏ {v}_{F}^{2}}{e} \sqrt{π {Q}_{gr , 0}^{i}} & {V}_{g}^{i} \geq {V}_{Dirac , 0}^{i} \\ {φ}_{Dirac} + \frac{ℏ {v}_{F}^{2}}{e} \sqrt{π {Q}_{gr , 0}^{i}} & {V}_{g}^{i} < {V}_{Dirac , 0}^{i}\end{matrix} \qquad ( 2.4 )$$

Firstly, if ϕ_{gr,0}ⁱ<ϕ_{HOMO,J}, electrons will hop from the fully filled HOMO of molecule to the Fermi surface of graphene and the adsorbed molecules behave like electron donors (n-type doping). The electrons in graphene are not able to hop into the empty LUMO of molecule due to the higher energy. Secondly, if ϕ_{gr,0}ⁱ>ϕ_{LUMO,J}, electron will hop from the Fermi surface of graphene to the LUMO of molecule and the adsorbed molecules behave like electron acceptors (p-type doping). Thirdly, the charge transfer will be forbidden if ϕ_{LUMO,J}>ϕ_{gr,0}ⁱ>g_{HOMO,J} or other unfavorable conditions happen, and gas molecules of this kind (third) are generally not of detection interest in this embodiment of the invention. At the equilibrium of charge transfer, the Fermi level of graphene will be pinned to the HOMO or LUMO energy level in the first or second due to the relative high density of states (DOS) of molecular orbital compared to that of graphene. Therefore, the charge density of graphene beneath the adsorbed molecule J after charge transfer, Q_{gr,J}ⁱ, can be calculated,

$${Q}_{gr , J}^{i} = \{ \begin{matrix}\frac{{e}^{2}}{{πℏ}^{2} {v}_{F}^{2}} ( {φ}_{HOMO , J} - {φ}_{Dirac} ) \vert {φ}_{HOMO , J} - {φ}_{Dirac} \vert & {φ}_{gr , 0}^{i} < {φ}_{HOMO , J} \\ \frac{{e}^{2}}{{πℏ}^{2} {v}_{F}^{2}} ( {φ}_{LUMO , J} - {φ}_{Dirac} ) \vert {φ}_{LUMO , J} - {φ}_{Dirac} \vert & {φ}_{gr , 0}^{i} > {φ}_{LUMO , J}\end{matrix} \qquad ( 5 )$$

where ϕ_{Dirac}=4.5 eV is the potential of the Dirac Point, v_{F}=10⁶ m/s is the Fermi velocity of electrons in graphene. It is important to note that the charge transfer is a local effect between the adsorbed molecule and the graphene, which means Q_{gr,J}ⁱ is the localized charge density of graphene nearby the adsorbed molecules. The overall charge density of graphene FET is the average of the density of both the pristine charge and the transferred charge,

$${Q}_{gr}^{i} = {Q}_{gr , 0}^{i} + {\sum }_{J = 1}^{{m}^{2}} {θ}_{J}^{i} ( {Q}_{gr , J}^{i} - {Q}_{gr , 0}^{i} ) \qquad ( 2.6 )$$

However the electrons in graphene, either pristine or transferred, are considered well delocalized in the FET, density of which is subject to the gate voltage modulation. Considering the amount of charge transferred to graphene per adsorbed molecule J, α_{J}=θ_{J}(Q_{gr,J}ⁱ−Q_{gr,0}ⁱ)/θ_{J}N_{gr}, α_{J} does not depend on the surface coverage rate θ_{J}ⁱ because θ_{J}ⁱ appears in both the nominator and the denominator, and it can be modulated by the gate voltage bias by substituting Q_{gr}^{i,0} using Eq. (2.2),

$${α}_{J} = \frac{{Q}_{gr , J}^{i} + {C}_{g} ( {V}_{g}^{i} - {V}_{Dirac , 0}^{i} )}{{N}_{gr}} \qquad ( 2.7 )$$

With Eq. (2.4), (2.5) and (2.7), we know that both the charge transfer direction and the amount of charge transferred to graphene per adsorbed molecule J can be modulated by the gate voltage, namely the DC offset voltage V_{G}ⁱ for its dominating amplitude. Usually α_{J} is a mild value within ±0.1e⁻ for physical adsorption, and the effective amount of modulation achieved by DC offset voltage is around ±0.01e⁻ depending on C_{g}. After charge transfer, the adsorbed molecules on the graphene surface will possess equal but opposite amount of charge −α_{J} due to charge neutrality, and become charged impurities on graphene, scattering the carrier transportation in the FET channel through the interaction of Coulomb force. The field effect mobility of electrons or holes limited by such charged impurity scattering in graphene FET is,

μ_{e/h,J}ⁱ⁻¹=Tα_{J}²θ_{J}ⁱN^{gr} (2.8)

where T=2.07×10⁻¹⁶ is a constant related to the screening property of graphene on the SiO₂ substrate. According to the Matthiessen's rule, the overall field effect mobility of electrons or holes in graphene FET is the summation of all contributing factors,

$${μ}_{elh}^{i - 1} = {μ}_{elh , 0}^{i - 1} + {\sum }_{J = 1}^{{m}^{2}} {μ}_{elh , J}^{i - 1} \qquad ( 2.9 )$$

where the second term in the right hand side of Eq. (2.9) is zero if the graphene FETs are in the idle state, and it can be tracked by measuring the small AC signal of channel current in real time using Eq. (2.1),

$${μ}_{elh}^{i - 1} - {μ}_{elh , 0}^{i - 1} = \frac{{C}_{g} {V}_{DS} W}{L} ( \vert \frac{{v}_{g}}{{i}_{ds}^{i}} \vert - \vert \frac{{v}_{g}}{{i}_{ds , 0}^{i}} \vert ) \qquad ( 2.10 )$$

Substituting Eq. (2.7) and (2.8) into (2.9),

$${μ}_{elh}^{i - 1} - {μ}_{elh , 0}^{i - 1} = {\sum }_{J = 1}^{{m}^{2}} {\frac{T}{{K}_{J}^{M} {N}_{gr}^{M}} [ {Q}_{gr , J}^{M} + {C}_{g} ( {V}_{G}^{i} - {V}_{Dirac , 0}^{M} ) ]}^{2} {P}_{J} = {M}_{iJ} {P}_{J} \qquad ( 2.11 )$$

where we assume K_{J}ⁱ=K_{J}^{M}, N_{gr}=N_{gr}^{M}, V_{Dirac,0}ⁱ=V_{Dirac,0}^{M}, Q_{gr,J}ⁱ=Q_{gr,J}^{M} being identical among the sensor array fabricated out in the same batch, and the quantities are labeled with “M” meaning they can be determined by previous measurement in the known environment. With m² different values of V_{G}ⁱ, the rank of matrix M_{iJ} is full meaning the inverse of M_{iJ} is always solvable. Therefore with M_{iJ}⁻¹ prepared, the gas partial pressure p, or the gas concentrations of each type in the mixture can be decoupled at the same time by reading the AC component of channel current (single identifier) in the sensor array,

P_{J}=M_{iJ}⁻¹(μ_{e/h}ⁱ⁻¹−μ_{e/h,0}ⁱ⁻¹) (2.12)

The contents of the following references are hereby incorporated by reference into the present application:
[1] C. yung Fu, “Artificial olfactory system,” 29 Jul. 2003.
[2] D. M. Adams, L. Brus, C. E. D. Chidsey, S. Creager, C. Creutz, C. R. Kagan, P. V. Kamat, M. Lieberman, S. Lindsay, R. a. Marcus, R. M. Metzger, M. E. Michel-Beyerle, J. R. Miller, M. D. Newton, D. R. Rolison, O. Sankey, K. S. Schanze, J. Yardley, and X. Zhu, “Charge Transfer on the Nanoscale: Current Status,” J. Phys. Chem. B, vol. 107, no. 28, pp. 6668-6697, 2003.
[3] A. Bayn, X. Feng, K. Muillen, and H. Haick, “Field effect transistors based on polycyclic aromatic hydrocarbons for the detection and classification of volatile organic compounds.,” ACS Appl. Mater. Interfaces, vol. 5, no. 8, pp. 3431-40, April 2013.
[4] S. R. Johnson, J. M. Sutter, H. L. Engelhardt, P. C. Jurs, J. White, J. S. Kauer, T. a Dickinson, and D. R. Walt, “Identification of Multiple Analytes Using an Optical Sensor Array and Pattern Recognition Neural Networks,” Differences, vol. 69, no. 22, pp. 4641-4648, 1997.
[5] F. Schedin, a K. Geim, S. V Morozov, E. W. Hill, P. Blake, M. I. Katsnelson, and K. S. Novoselov, “Detection of individual gas molecules adsorbed on graphene.,” Nat. Mater., vol. 6, no. 9, pp. 652-655, 2007.
[6] J.-H. Chen, C. Jang, S. Adam, M. S. Fuhrer, E. D. Williams, and M. Ishigami, “Charged-impurity scattering in graphene,” Nature Physics, vol. 4, no. 5. pp. 377-381, 2008.
[7] H. E. Romero, P. Joshi, A. K. Gupta, H. R. Gutierrez, M. W. Cole, S. a Tadigadapa, and P. C. Eklund, “Adsorption of ammonia on graphene.,” Nanotechnology, vol. 20, no. 24, p. 245501, 2009.
[8] H. H. Pu, S. H. Rhim, M. Gajdardziksa-Josifovska, C. J. Hirschmugl, M. Weinert, and J. H. Chen, “A statistical thermodynamics model for monolayer gas adsorption on graphene-based materials: implications for gas sensing applications,” RSC Adv., vol. 4, no. 88, pp. 47481-47487, 2014.
[9] S. Adam, E. H. Hwang, V. M. Galitski, and S. Das Sarma, “A self-consistent theory for graphene transport.,” Proc. Natl. Acad. Sci. U.S.A., vol. 104, no. 47, pp. 18392-18397, 2007.

### Example 3

The following example describes a technique to selectively sense different gases using a single graphene field effect transistor (FET) by measuring real time conductance as a function of gate voltage according to an embodiment of the current invention. Compared to the state-of-art, three distinctive advancements in this example have been achieved: (1) first demonstration of selective gas sensing (NO₂, NH₃, H₂O and CH₃OH) using a single graphene FET; (2) experimental proof of linear dependence between the reciprocal of carrier mobility limited by long-range scattering and the Dirac Point voltage upon gas molecule exposure; (3) utilizations of such linear characteristic for selective gas sensing. As such, the sensing scheme and results according to this embodiment of the current invention could open up a new class of graphene-based, selective gas sensing devices for practical uses as well as for fundamental scientific research.

In recent years, graphene based gas sensors have drawn great interest due to their ultra large surface to volume ratio and semiconducting properties. It has been reported that the resistance of graphene FET is very sensitive to the exposure of several types of gases, i.e. NH₃, NO₂ and H₂O [1], and the corresponding limit of detection (LOD) can reach the single molecular level [2]. The key gas sensing mechanism for a graphene FET is the surface charge transfer. For example, an ammonia molecule adsorbed on a graphene FET can act as a temporary dopant to donate electrons and lower the channel resistance by increasing the carrier concentration. Since the charge transfer process can take place at room temperature, graphene-FET-based gas sensors are not required to operate at an elevated temperature and they can operate with very low power consumption, e.g., around microwatt [3]. An extensive amount of research has discussed the sensitivity of graphene gas sensors without addressing the issue of sensing selectivity. Previously, a couple of approaches have been proposed for gas sensing selectivity with a tedious AFM (Atomic Force Microscope) setup [4], or complicated noise measurements schemes [5]. These approaches are not feasible for practical uses. In this example, we demonstrate the capability to distinguish four types of gases (NO₂, NH₃, H₂O and CH₃OH) by measuring the real time shift of conductance versus gate voltage of a single graphene FET at room temperature. By exploring the linear dependence between the reciprocal of the carrier mobility limited by the long-range scattering and the Dirac Point voltage of a graphene FET, we experimentally demonstrate the slope of such linear dependence is unique to tested gases for the differentiation and selective sensing.

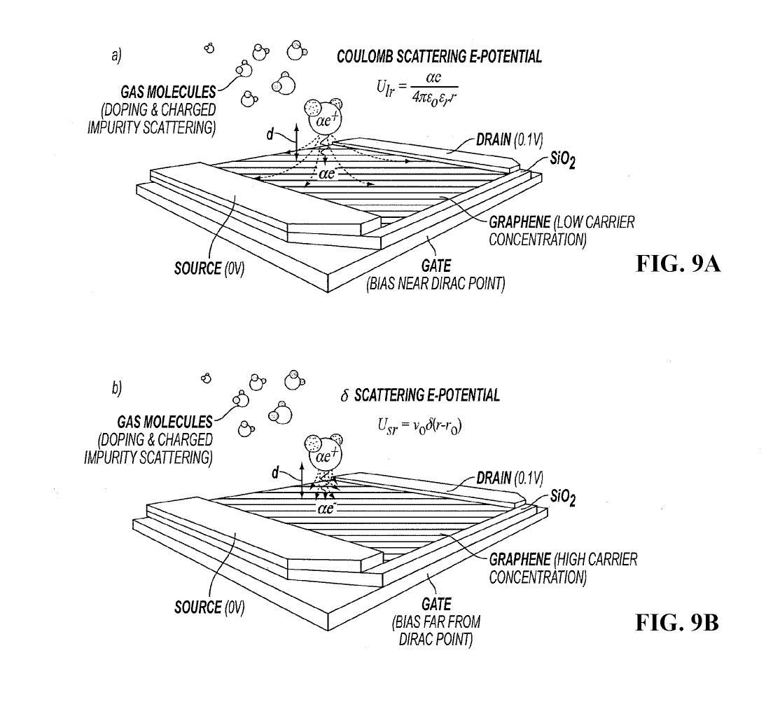

It is well known that the carrier mobility on graphene at room temperature is mostly limited by the scattering of carriers due to charged impurity, instead of due to phonons [6]. The charged impurity can be found on both surfaces (top and bottom) of graphene. As shown in FIGS. 9A-9B, a gas molecule on the top surface of graphene becomes a positively charged impurity after donating a electrons from its molecular orbital to graphene. This effect will change and the Dirac Point voltage and the carrier mobility of the graphene FET due to the change in 1) the carrier concentration, n, of graphene, and 2) the charged impurity concentration, nᵢₘₚ, on top of graphene, respectively. The charged impurity can behave differently depending on the screening environment provided by the carriers in graphene. FIG. 9A shows a single charged impurity scatters the carriers in a long-range manner with the electrical scattering potential following Coulomb's law. This happens when the carrier concentration is small as compared with the charged impurity concentration, or the gate voltage is biased near the Dirac Point. On the other hand, FIG. 9B shows a single charged impurity scatters the carriers in a short-range manner with the electrical scattering potential being a delta function, where r₀ is the position of the charged impurity. This happens when the carrier concentration is high as compared with charged impurity and the Coulomb scattering potential is completely screened by the carriers in graphene.

It is known that for short-range scattering the mean free path lₛᵣ˜1/\sqrt{n}, where n is the carrier concentration, and for long-range scattering the mean free path l_{c}˜\sqrt{n} [6]. The carrier concentration of graphene FET can be modulated by the gate voltage,

n=c_{g}(V_{g}−V_{g,Dirac}) (3.1)

where V_{g} is the gate voltage, c_{g} is the gate capacitance per unit area, or 1.2×10⁻⁴ Fm⁻² for the 300 nm SiO₂ gate dielectric material used in the prototype devices. At low carrier concentration of n≈nᵢₘₚ in the order of 10¹¹ cm⁻², one can estimate that lₛᵣ˜1,000 nm and l_{c}˜50 nm. Therefore, when the gate voltage is biased near to the Dirac point (lowest carrier concentration), graphene transport is dominated by the long-range scattering, with carrier mobility:

$${μ}_{e} = {μ}_{e , c} = \frac{{C}_{e}}{{n}_{imp}} \\ {μ}_{h} = {μ}_{h , c} = \frac{{C}_{h}}{{n}_{imp}} \qquad ( 3.2 )$$

where μₑ and μₕ are the electron and hole field-effect mobility, μ_{e,c} and μ_{h,c} are electron and hold long-range scattering limited field-effect mobility, Cₑ and Cₕ are gas-unique constants that are only relevant to the band structure of graphene, c_{g}, α and d (see FIGS. 9A-9B). If the channel length in the graphene FET (˜um) is much larger than the typical mean free path (˜nm), the diffusive Drude-Boltzmann model can be adopted to derive the conductance σ(V_{g}) of graphene [7]:

$$σ ( {V}_{g} ) = \{ \begin{matrix}{μ}_{e} {c}_{g} ( {V}_{g} - {V}_{g , Dirac} ) + {σ}_{Dirac} & {V}_{g} > {V}_{g , Dirac} \\ - {μ}_{h} {c}_{g} ( {V}_{g} - {V}_{g , Dirac} ) + {σ}_{Dirac} & {V}_{g} < {V}_{g , Dirac}\end{matrix} \qquad ( 3.3 )$$

where σ_{Dirac} is the residual conductance at the Dirac Point. The Dirac Point voltage is the gate voltage at the minimum point of the conductance, and the majority carrier is electron/hole if the gate voltage V_{g} is bigger/smaller than V_{g,Dirac}.

When exposed to a particular gas, it is assumed that gas molecules adsorb on graphene surface gradually, namely the gas molecule per unit area on graphene, N_{gas}(t), increases linearly with respect to the exposure time, t, in the initial stage. As such, both n and nᵢₘₚ also vary linearly with time, or Δn(t)˜N_{gas}(t) and Δnᵢₘₚ(t)˜N_{gas}(t). According to Eq. (3.1) and (3.2), one can observe that the Dirac Point voltage and the reciprocal of long-range scattering limited mobility will also vary with time linearly, or ΔV_{g,Dirac}(t)˜N_{gas}(t)/c_{g} and Δ[1/μ_{e/h,c}(t)]˜N_{gas}(t)/C_{e/h}. Interestingly, the ratio between the two quantity, Δ[1/μ_{e/h,c}(t)]/ΔV_{g,Dirac}(t)˜c_{g}/C_{e/h}, which is a gas related constant and will not change with the exposure time. Therefore we can parameterize the above-mentioned ratio as the “linear factor” and use it to label different gas molecules on the graphene FET. As such, a single graphene FET can be used to detect different types of gas molecule selectively by characterizing the linear factor from real time measurements.

### Fabrication

Firstly, the high quality monolayer graphene sheet is synthesized via chemical vapor deposition (CVD) on a copper foil under 1000° C. and transferred with wet approach onto a thermally grown 300 nm-thick SiO₂ on a p-doped silicon wafer as described in our previous work [3]. The source and drain electrodes are deposited and patterned by Cr/Au (3 nm/50 nm) e-beam evaporation using the lift off process. The graphene channel is patterned and etched by a 50 W oxygen plasma process for 7 s using the standard optical lithography process. The whole device is then spin-coated with a 1 um-thick, 20% w.t. polyethylenimine (PEI) and left for 2 h before thoroughly rinsed in DI water. This creates a thin layer of residual PEI on graphene as the n-type dopant to adjust the Dirac Point of graphene FET at around 0V.

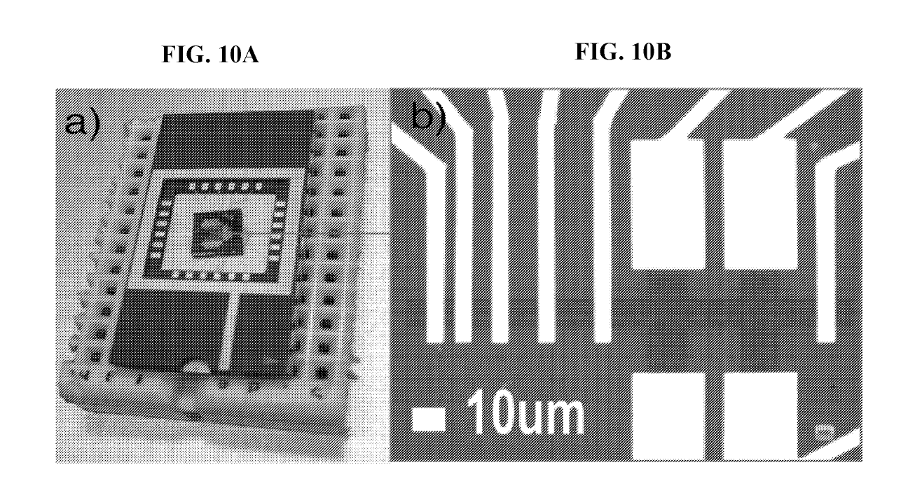

FIGS. 10A-10B show the gas sensor package installed on a breadboard, and the microscopic optical picture of the as-fabricated graphene FETs. The monolayer graphene channel can be seen on the SiO₂ substrate. The transfer length method [8] is used to determine the contact resistance between the source/drain electrode and the monolayer graphene as ˜100Ω. The “Hall bar” structure in FIGS. 10A-10B is used to measure the pristine (before exposure to gas molecules) of the carrier (electron/hole) mobility of graphene by the hall effect mechanism [2] and a representative mobility value for the prototype device is around 1000 cm²/Vs.

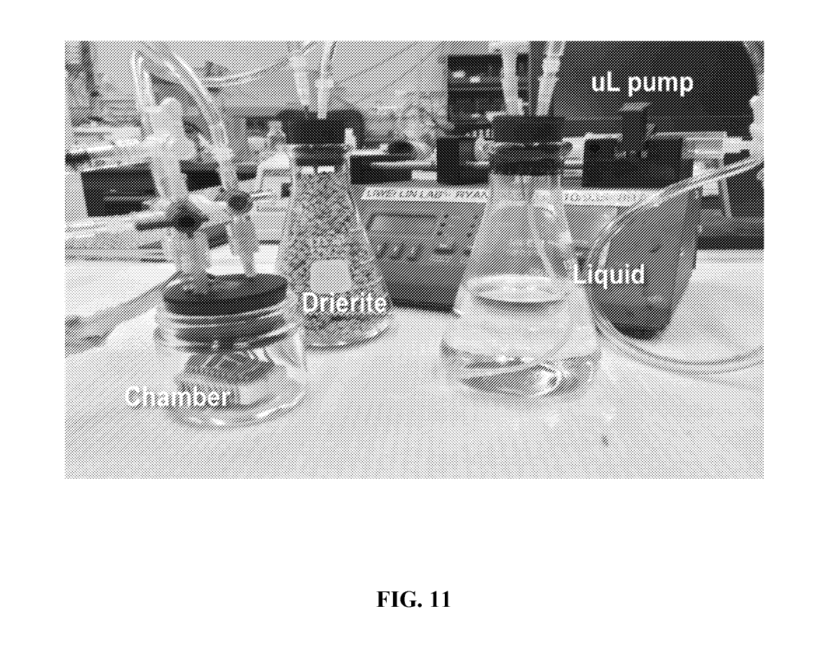

FIG. 11 is an optical photo of the gas sensor testing setup. The graphene FET is sealed in the chamber, under ambient atmosphere and room temperature. A microliter pump (New Era Pumping Systems NE-300) is used to pump into the liquid chemicals to produce gas vapors into the sensing chamber, while water vapors are extracted out by using the drying agent. This system can control gas vapor inputs at the level of 100 ppm/s. A semiconductor parameter analyzer (Agilent 4145B) is used to measure the graphene channel conductance versus gate voltage (−40V<V_{g}<40V), while the voltage between the source and drain electrode is V_{DS}=0.1V throughout the experiment. The semiconductor analyzer is controlled with a Labview program, while the characteristics of the graphene FET are calculated using a Matlab program afterwards.

### Results and Discussion

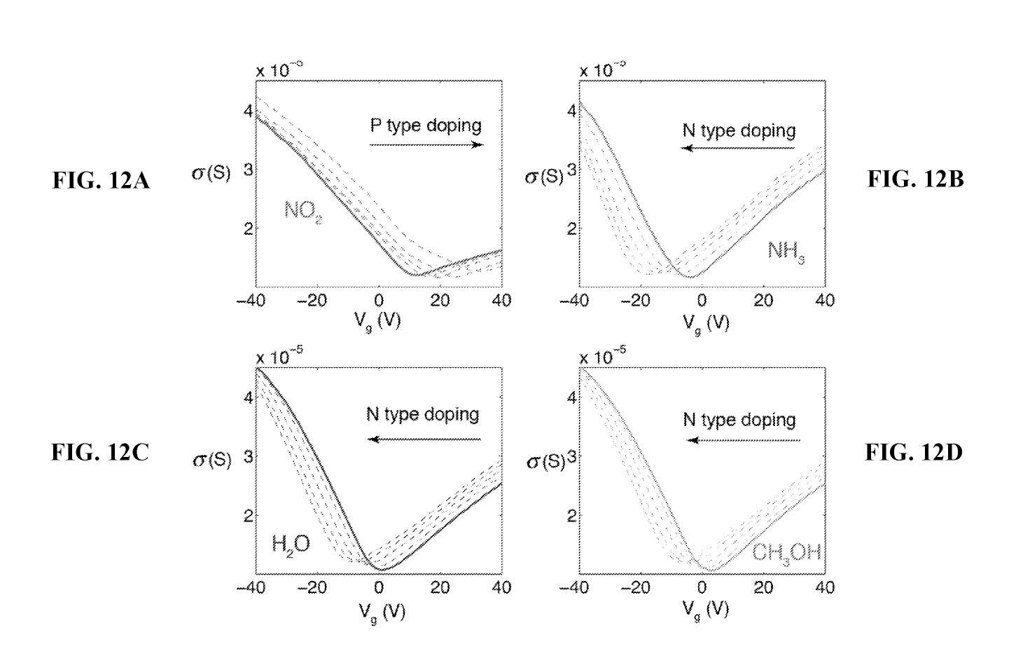

The sensing cycle starts from measuring the conductance versus gate voltage curve of the sealed graphene FET in its idle state (without gas). The microliter pump is turned on manually at a desired pumping speed and the gas vapor starts to enter the chamber. The semiconductor parameter analyzer measures the conductance versus gate voltage curves for several times to characterize the concentration changes of the input gas. In the prototype tests, the interval between these measurements is set at 15 seconds. After the pump is turned off, the gas sensor is released to the ambient atmosphere by opening the chamber lid. FIGS. 12A-12D show the real time conductance versus gate voltage of graphene FET measurements during the exposure of NO₂, NH₃, H₂O and CH₃OH vapors, respectively. The solid curves are the idle state (before gas vapor exposure), and the dashed curves are doped states. The gas vapor flow rate in the chamber is set at a constant value around 750 ppm/s. As indicated in FIG. 12A that NO₂ vapor accepts electrons from graphene such that the Dirac Point voltage shifts positively as ΔV_{g,Dirac}(t)/Δt>0. In the case of NH₃, H₂O and CH₃OH, these vapors donate electrons to graphene such that the Dirac Point voltage shifts negatively, as ΔV_{g,Dirac}(t)/Δt<0.

One can derive μ_{e/h}(V_{g}) for each σ(V_{g}) using Eq. (3.3), and derive the long-range limited mobility μ_{e/h,c}=μ_{e/h}(V_{g,c}) at gate voltage V_{g,c} nearby the Dirac Point. In this example, we choose V_{g,c}=V_{g,Dirac}±2V to derive the corresponding real time long-range scattering limited mobility μ_{e/h,c}(t). It is important to note that the calculation of μ_{e/h,c}(t) does not rely on the choice of V_{g,c} because the long-range scattering limited mobility is relevant to the concentration of charge impurity and not sensitive to the carrier concentration, or the choice of V_{g,c}. If the applied gate voltage is far away from the Dirac Point, the scattering potential goes into the short-range scattering regime.

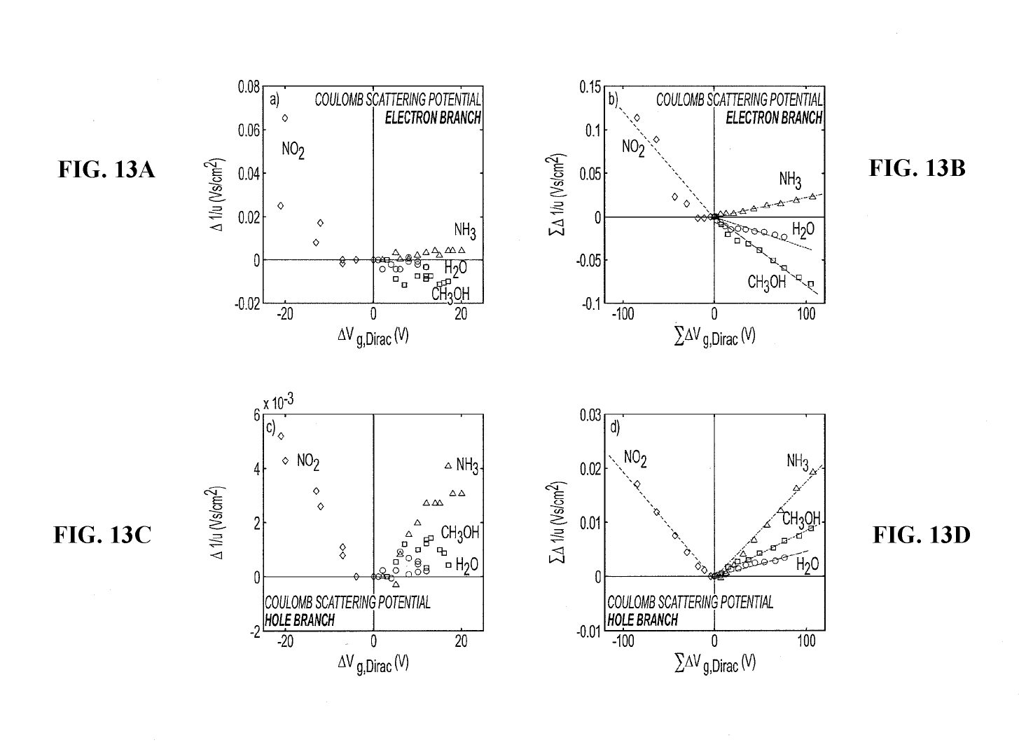

FIGS. 13A and 13C are as-calculated real time reciprocal of the long-range scattering limited mobility Δ[1/μ_{e/h,c}(t)] versus the Dirac Point voltage ΔV_{g,Dirac}(t) for the electron and hole regimes, respectively. Each data point represents a specific exposure time of graphene FET to a particular gas. The linear dependence between Δ[1/μ_{e/h,c}(t)] and ΔV_{g,Dirac}(t) is expected but not well demonstrated in the prototype measurements. This is due to the measurement errors as well as the noises in the testing system. In order to reduce the randomness for better linearity presentation, we take the summations of the data points as (xᵢ′, yᵢ′) as defined by:

$${x}_{i}^{′} = {\sum }_{j = 1}^{i} {x}_{j} \\ {y}_{i}^{′} = {\sum }_{j = 1}^{i} {y}_{j} \qquad ( 3.4 )$$

FIGS. 13B and 13D show the summation results have clearer linearity presentation with the linear factors at different gas exposure time and clearly different between the four gases.

TABLE 1
Linear Factor Fitting Result (norm of residuals)

| | Hole Regime × 10⁻⁴ | Electron Regime × 10⁻⁴ |
|---|---|---|
| Gas | (norm of residuals) | (norm of residuals) |
| NO₂ | −1.975 (0.0023) | −12.94 (0.0436) |
| NH₃ | 1.870 (0.0021) | 2.113 (0.0023) |
| H₂O | 0.465 (0.0008) | −2.763 (0.0099) |
| CH₃OH | 0.796 (0.0011) | −7.088 (0.0120) |

The linear factor of each gas vapor is further fitted using the data points in FIGS. 13B and 13D and the fitting results and the norm of residuals are shown in Table 1. It is observed that the norm of residuals for NO₂ in the electron regime is larger than results in other regime. This is because less data are collected in the prototype tests (see FIG. 12A) as the maximum applied gate voltage (40V) is close to the Dirac Point of NO₂ doped graphene FET. The problem can be alleviated by extending the applied gate voltages to higher values.

### CONCLUSION

We have successfully demonstrated the technique to detect NO₂, NH₃, H₂O and CH₃OH vapors selectively using a single graphene FET gas sensor according to an embodiment of the current invention. By measuring the conductance versus gate voltage of a graphene FET, one can derive the unique long-range scattering limited carrier mobility μ_{e/h,c}(t) and the Dirac Point voltage V_{g,Dirac}(t) for each gas in real time. Experimentally, we have validated that different types of gases have their own specific ratio of Δ[1/μ_{e/h,c}(t)]/ΔV_{g,Dirac}(t), defined as the linear factor. As such, a single graphene FET can be used to detect a particular type of gas molecule selectively by measuring the linear factor.

### REFERENCES FOR EXAMPLE 3

[1] W. Yuan, “Graphene-based gas sensors”, Journal of Material Chemistry A, 2013, 1, 10078-10091
[2] F. Schedin, “Detection of individual gas molecules absorbed on graphene”, Nature Materials, 2007, 6, pp. 652-655
[3] Y. Liu, “A Flexible Graphene FET Gas Sensor Using Polymer as Gate Dielectrics”, 2014 IEEE 27th International Conference on Micro Electro Mechanical Systems (MEMS), pp. 230-233, San Francisco, January 2013.
[4] M. Qazi, T. Vogt, G. Koley, “Two-dimensional signatures for molecular identification”, Applied Physcis Letters 92, 103120, 2008
[5] S. Rumyantsev, G. Liu, A. Baladin, “Selective Gas Sensing with A Single Pristine Graphene Transistor”, Nano Lett. 12, 2294-2298, 2012
[6] S. Adam, “A Self-consistent theory of graphene transport”, Proceedings of the National Academy of Sciences of the United States of Americal, 2007, vol. 104 No. 47, 18392-18397
[7] J. Chen, “Charged-impurity scattering in graphene”, Nature Physics, 4(2008) pp. 377-381
[8] F. Xia, “The origins and limits of metal-graphene junction resistance”, Nature Nanotechnology, 6(2011) pp. 179-184

The embodiments illustrated and discussed in this specification are intended only to teach those skilled in the art how to make and use the invention. In describing embodiments of the invention, specific terminology is employed for the sake of clarity. However, the invention is not intended to be limited to the specific terminology so selected. The above-described embodiments of the invention may be modified or varied, without departing from the invention, as appreciated by those skilled in the art in light of the above teachings. It is therefore to be understood that, within the scope of the claims and their equivalents, the invention may be practiced otherwise than as specifically described.

1. A gas detection system for selectively detecting one or more gases from a mixture of gases, comprising:
a gas sensor comprising at least one graphene field effect transistor (GFET), said GFET comprising:
a source electrode,
a drain electrode spaced apart from said source electrode,
a graphene channel layer extending between and in electrical connection with said source and drain electrodes, said graphene channel layer having at least a portion of a surface thereof exposed to be able to make contact with a gas sample,
a gate electrode arranged proximate said graphene channel layer, and
a dielectric layer between said graphene channel layer and said gate electrode;
a modulation system electrically connected to said gate electrode to modulate a response of said GFET to said gas sample;
a detector electrically connected to said source electrode and said drain electrode to detect a modulated signal containing information concerning a response of said GFET to said gas sample during modulation by said modulation system; and
a signal processor configured to communicate with said detector to receive said modulated signal,
wherein said signal processor is further configured to selectively determine a concentration of at least one gas in said gas sample based at least on said modulated signal.

2. The gas detection system of claim 1, wherein said signal processor is further configured to selectively determine a concentration of each of a plurality of gases in said gas sample based at least on said modulated detection signal.

3. The gas detection system of claim 1, wherein said modulation system applies a plurality of gate voltages to said GFET at a corresponding plurality of different times such that said detector provides a plurality of modulated detection signals to said signal processor, and
wherein said signal processor is further configured to selectively determine a concentration of each of a plurality of gases in said gas sample based at least on said plurality of modulated detection signals.

4. The gas detection system of claim 3, wherein said plurality of detection signals provide information concerning a plurality of response-influencing parameters, and
wherein said signal processor is further configured to selectively determine said concentration of each of said plurality of gases in said gas sample based at least partially on said information concerning said plurality of response-influencing parameters.

5. The gas detection system of claim 4, wherein said plurality of response-influencing parameters include at least field effect mobility, effective mobility, hall effect mobility, carrier concentration, Dirac Point voltage, conductivity, noise spectral density, contact resistance, or work function.

6. The gas detection system of claim 1, wherein said gas sensor comprises a plurality of GFETs, each GFET comprising:
a source electrode,
a drain electrode spaced apart from said source electrode,
a graphene channel layer extending between and in electrical connection with said source and drain electrodes, said graphene channel layer having at least a portion of a surface thereof exposed to be able to make contact with a gas sample to be detected,
a gate electrode arranged proximate said graphene channel layer, and
a dielectric layer between said graphene channel layer and said gate electrode,
wherein said modulation system is electrically connected to said gate electrode of each GFET of said plurality of GFETs to modulate a response of each GFET to said gas sample,
wherein said detector is electrically connected to said source electrode and said drain electrode of each GFET of said plurality of GFETs to detect a plurality of modulated signals containing information concerning a response of each corresponding GFET of said plurality of GFETs to said gas sample during modulation by said modulation system,
wherein said signal processor is configured to communicate with said detector to receive said plurality of modulated signals, and
wherein said signal processor is further configured to selectively determine a concentration of at least one gas in said gas sample based at least on said plurality of modulated signals.

7. The gas detection system of claim 6, wherein said signal processor is further configured to selectively determine a concentration of each of a plurality of gases in said gas sample based at least on said plurality of modulated detection signals

8. The gas detection system of claim 2, wherein said signal processor is further configured to determine said concentration of each of said plurality of gases in said gas sample using previous knowledge of responses of said GFET to known gases.

9. The gas detection system of claim 2, wherein said signal processor is further configured to determine said concentration of said plurality of gases in said gas sample based on previous knowledge of responses of said GFET to known gases that include said plurality of gases by at least one of solving a set of linear equations, using machine learning, using principle component analysis, using a numerical fitting routine, or using an analytical fitting routine.

10. A gas-detection method, comprising:
exposing a GFET to a gas sample, said GFET comprising:
a source electrode,
a drain electrode spaced apart from said source electrode,
a graphene channel layer extending between and in electrical connection with said source and drain electrodes, said graphene channel layer having at least a portion of a surface thereof exposed to be able to make contact with said gas sample,
a gate electrode arranged proximate said graphene channel layer, and
a dielectric layer between said graphene channel layer and said gate electrode;
modulating a response of said GFET to said gas sample by controlling a voltage applied to said gate electrode;
detecting a response of said GFET during said modulating to provide a modulated signal; and
processing said modulated signal to selectively determine a concentration of at least one gas in said gas sample.

11. The gas-detection method of claim 10, wherein said processing further comprises selectively determining a concentration of each of a plurality of gases in said gas sample based at least on said modulated detection signal.

12. The gas-detection method of claim 10, wherein said modulating further comprises applying a plurality of gate voltages to said GFET at a corresponding plurality of different times such that said detecting provides a plurality of modulated detection signals, and
wherein said processing further comprises selectively determining a concentration of each of a plurality of gases in said gas sample based at least on said plurality of modulated detection signals.

13. The gas-detection method of claim 12, wherein said plurality of detection signals provide information concerning a plurality of response-influencing parameters, and
wherein said processing further comprises selectively determining said concentration of each of said plurality of gases in said gas sample based at least partially on said information concerning said plurality of response-influencing parameters.

14. The gas-detection method of claim 13, wherein said plurality of response-influencing parameters include at least field effect mobility, effective mobility, hall effect mobility, carrier concentration, Dirac Point voltage, conductivity, noise spectral density, contact resistance, or work function.

15. The gas-detection method of claim 10, further comprising exposing a plurality of GFETs to said gas sample, said GFET comprising:
a source electrode,
a drain electrode spaced apart from said source electrode,
a graphene channel layer extending between and in electrical connection with said source and drain electrodes, said graphene channel layer having at least a portion of a surface thereof exposed to be able to make contact with a gas sample to be detected,
a gate electrode arranged proximate said graphene channel layer, and
a dielectric layer between said graphene channel layer and said gate electrode,
modulating a response of said plurality of GFETs to said gas sample by controlling a voltage applied to said gate electrodes;
detecting a response of said plurality of GFETs during said modulating to provide a plurality of modulated signals; and
processing said modulated signals to selectively determine a concentration of at least one gas in said gas sample.

16. The gas-detection method of claim 15, wherein said processing further comprises selectively determining a concentration of each of a plurality of gases in said gas sample based at least on said plurality of modulated detection signals

17. The gas-detection method of claim 11, wherein said processing further comprises determining said concentration of each of said plurality of gases in said gas sample using previous knowledge of responses of said GFET to known gases.

18. The gas-detection method of claim 11, wherein said processing further comprises determining said concentration of said plurality of gases in said gas sample based on previous knowledge of responses of said GFET to known gases that include said plurality of gases by at least one of solving a set of linear equations, using machine learning, using principle component analysis, using a numerical fitting routine, or using an analytical fitting routine.
